(19) United States
(12) Patent Application Publication
(10) Pub. No.: US 2016/0163659 A1
(43) Pub. Date: Jun. 9, 2016

(54) RADIO FREQUENCY DEVICE PROTECTED AGAINST OVERVOLTAGES

(71) Applicant: STMicroelectronics (Tours) SAS, Tours (FR)

(72) Inventors: Erwan Bruno, Ballan-Mire (FR); Abdelali Zaid, Cerelles (FR)

(73) Assignee: STMICROELECTRONICS (TOURS) SAS, Tours (FR)

(21) Appl. No.: 14/844,626

(22) Filed: Sep. 3, 2015

(30) Foreign Application Priority Data
Dec. 8, 2014 (FR) 1462023

(51) Int. Cl. H01L 23/66; H01L 21/84; H01L 21/306; H01L 27/02; H01L 27/12

(52) U.S. Cl. CPC H01L 23/66; H01L 27/0255; H01L 27/1203; H01L 21/30604; H01L 21/84; H01L 2223/6661

(57) ABSTRACT

A device includes passive radio frequency components formed of portions of metal layers separated by insulating layers and crossed by vias. The insulating layers are positioned on an upper surface of an insulating substrate. Islands of a semiconductor material extend into the insulating substrate from the upper surface. Active integrated circuit components are formed in the islands.

### PRIORITY CLAIM

This application claims the priority benefit of French Application for Patent No. 1462023, filed on Dec. 8, 2014, the contents of which is hereby incorporated by reference in its entirety to the maximum extent allowable by law.

### TECHNICAL FIELD

The present disclosure relates to a device comprising radio frequency circuits comprising passive components formed from portions of metal layers separated by insulating layers crossed by vias, the passive radio frequency components being associated with circuits of protection against overvoltages. The present disclosure also relates to a method of manufacturing such a device.

### BACKGROUND

To protect against an overvoltage, for example against an electrostatic discharge (ESD), in a radio frequency circuit comprising passive components such as capacitors or inductances, it is conventional to connect a protection circuit in parallel to this radio frequency circuit.

FIG. 1 shows in the form of a block diagram a radio frequency circuit 1 such as a filter and an example of a circuit 3 of protection against overvoltage. Circuits 1 and 3 are connected in parallel between a terminal IN and a terminal GND. Protection circuit 3 comprises a diode 5 connected in parallel with a series connection of a diode 7 and of a protection diode 9. Anode 11 and cathode 13 of diode 5 are respectively connected to terminal IN and to terminal GND. Cathode 15 and anode 17 of diode 7 are respectively connected to terminal IN and to anode 19 of diode 9, cathode 21 of diode 9 being connected to terminal GND.

In operation, a radio frequency signal having its nominal voltage varying between a negative voltage and a zero voltage is applied between terminals IN and GND, terminal GND being at a zero voltage. If a negative overvoltage exceeding the sum of the threshold voltage of diode 7 and of the avalanche voltage of protection diode 9 occurs on terminal IN, diodes 7 and 9 become conductive. If a positive overvoltage exceeding the threshold voltage of diode 5 occurs on terminal IN, diode 5 becomes conductive.

The biasing for diodes 5, 7, and 9 of protection circuit 3 will be inverted in the case where the nominal voltage of the radio frequency signal is positive.

There exist various devices associating overvoltage protection circuits with radio frequency circuits comprising passive components. In certain devices, the radio frequency circuits are formed on a first chip made of an insulating material and the protection circuits are formed in a second chip made of a semiconductor material. In other devices, the radio frequency circuits are formed in insulating layers laid on a semiconductor substrate, and the protection circuits are formed in this substrate. A disadvantage of these other devices is that, in operation, radio frequency waves radiate in the semiconductor substrate and generate a power dissipation due, for example, to the appearing of eddy currents.

It would thus be desirable to have a device comprising passive radio frequency circuits protected against overvoltage which overcomes the disadvantages of existing devices.

### SUMMARY

Thus, an embodiment provides a device comprising passive radio frequency components formed of portions of metal layers separated by insulating layers crossed by vias and laid on the upper surface of an insulating substrate, wherein islands of a semiconductor material extend into the insulating substrate from its upper surface, active components being formed in these islands.

According to an embodiment, a circuit of protection against overvoltage is formed from at least some of the active components.

According to an embodiment, the active components are connected to the passive radio frequency components.

According to an embodiment, the resistivity of the insulating substrate is greater than 10³ Ω·cm.

According to an embodiment, a silicon oxide layer separates the substrate from the semiconductor material of the islands.

According to an embodiment, the substrate is made of glass.

According to an embodiment, the semiconductor material of the islands is lightly doped with a first conductivity type and comprises a heavily-doped layer of the second conductivity type arranged on the edges and the bottom of each island, the semiconductor material of at least one of the islands further comprising a heavily-doped region of the second conductivity type extending from the top of this island, and a heavily-doped region of the first conductivity type in contact, at the bottom of this island, with the heavily-doped layer of the second conductivity type.

Another aspect provides a method of manufacturing a device comprising the successive steps of: a) etching a first surface of a doped semiconductor substrate of a first conductivity type so that the semiconductor substrate exhibits protrusions; b) forming a doped layer of the second conductivity type on the first surface of the semiconductor substrate; c) arranging an insulating substrate covering and following the shape of the first surface of the semiconductor substrate; d) removing by planarizing etching the semiconductor substrate all the way to its first surface so that there remains in the insulating substrate semiconductor islands corresponding to said protrusions; and e) forming passive radio frequency components by depositing and etching insulating layers and metal layers on the planarized surface.

According to an embodiment, between step d) and step e), a doped region is formed in at least one island.

According to an embodiment, before step a), another doped region is formed in the semiconductor substrate at a location corresponding to a protrusion.

According to an embodiment, the etching conditions of step a) are selected so that the protrusions have inclined sides.

### BRIEF DESCRIPTION OF THE DRAWINGS

The foregoing and other features and advantages will be discussed in detail in the following non-limiting description of specific embodiments in connection with the accompanying drawings, wherein:

FIG. 1, previously described, shows a radio frequency circuit connected to an overvoltage protection circuit;

FIG. 2 is a cross-section view schematically showing an embodiment of an example of a device comprising passive radio frequency components protected against overvoltage; and

FIGS. 3A to 3E are simplified cross-section views illustrating successive steps of an example of a method of manufacturing the device of FIG. 2.

### DETAILED DESCRIPTION

The same elements have been designated with the same reference numerals in the various drawings and, further, the various drawings are not to scale.

In the following description, when reference is made of terms qualifying position and orientation such as “above”, “upper”, “lower”, “inclined”, “bottom”, “top”, etc., reference is made to the orientation of the targeted elements in the concerned drawings.

Unless otherwise mentioned, term “substantially” means “to within 10%”, and preferably “to within 5%”.

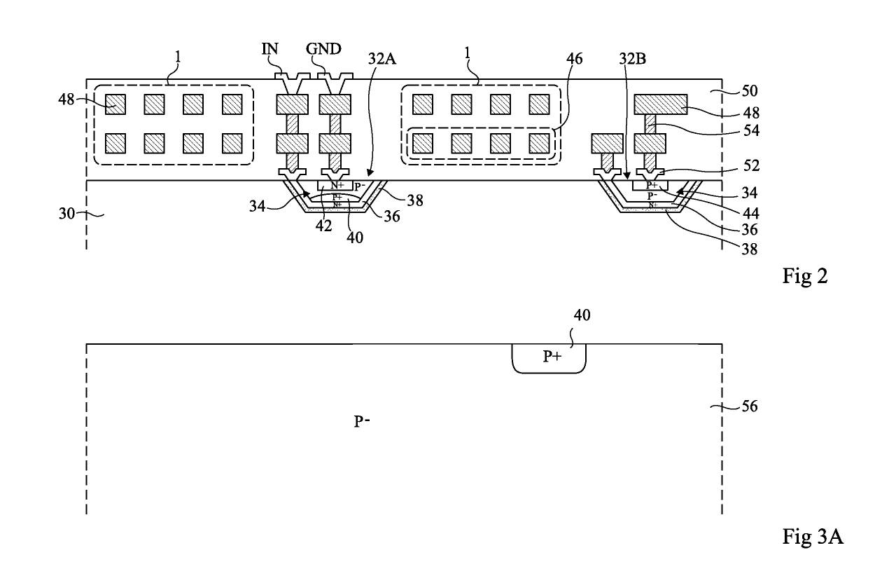

FIG. 2 is a cross-section view schematically showing an embodiment of an example of a device comprising a radio frequency circuit associated with an overvoltage protection circuit.

The device comprises an insulating substrate 30 where islands, two islands 32A and 32B in this example, extend from the upper surface of substrate 30 down to a limited depth. “Insulating substrate” here designates a substrate having a resistivity greater than 10³ Ω·cm.

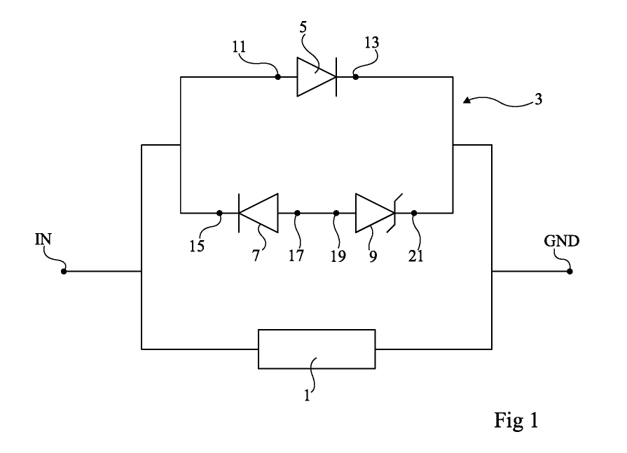

Islands 32A and 32B are made of a lightly-doped P-type semiconductor material 34 (P⁻). Semiconductor material 34 comprises a heavily-doped N-type layer 36 (N⁺) arranged on the edges and the bottom of each island. As shown in FIG. 2, semiconductor material 34 may be separated from the material of substrate 30 by an optional insulating layer 38 such as a silicon oxide layer. In this example, semiconductor material 34 of island 32A further comprises a heavily-doped P-type region 40 (P⁺) in contact, at the bottom of this island, with a portion of layer 36, and a heavily-doped N-type region 42 (N⁺) extending from the top of the island. Further, semiconductor material 34 of island 32B comprises a heavily-doped P-type region 44 (P⁺) extending from its upper surface. Thus, the junctions between region 42 (N⁺) and material 34 (P⁻) of island 32A, between layer 36 (N⁺) and region 40 (P⁺) of island 32A, and between layer 36 (N⁺) and material 34 (P⁻) of island 32B respectively form diodes 7, 9, and 5 of an overvoltage protection circuit of the type shown in FIG. 1.

The device also comprises a radio frequency circuit 1 comprising passive components 46 formed from portions of metal layers 48 separated by insulating layers 50, the assembly of insulating layers 50 resting on the upper surface of substrate 30. Radio frequency circuit 1 may be a film formed of inductances, of capacitors, and/or of resistors. Pads IN and GND are formed at the level of the upper surface of the assembly of insulating layers 50. In insulating layers 50, pads 52, vias 54, and portions of metal layers 48 connect filter 1, diodes 5, 7, and 9, and pads IN and GND as described in relation with FIG. 1, a portion only of these connections being shown in FIG. 2. Thus, in this example, pad IN is connected to layer 36 of island 32A and to layer 36 of island 32B, and pad GND is connected to region 42 of island 32A and to region 44 of island 32B.

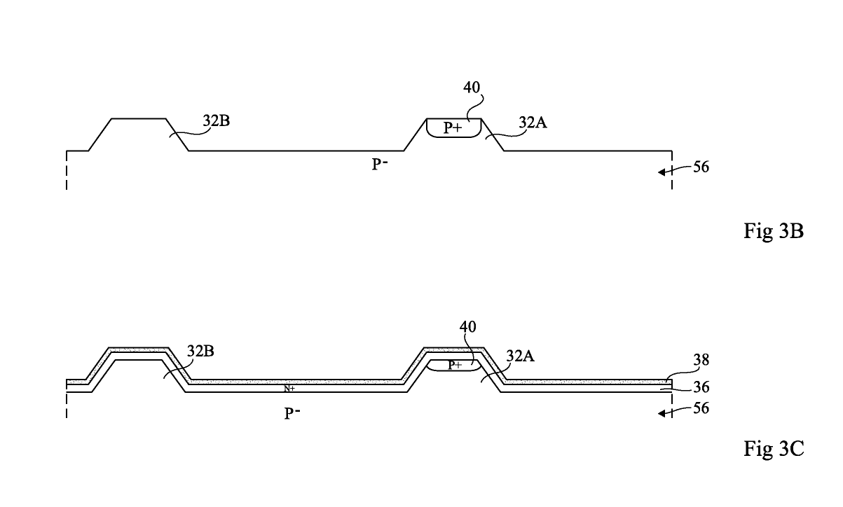

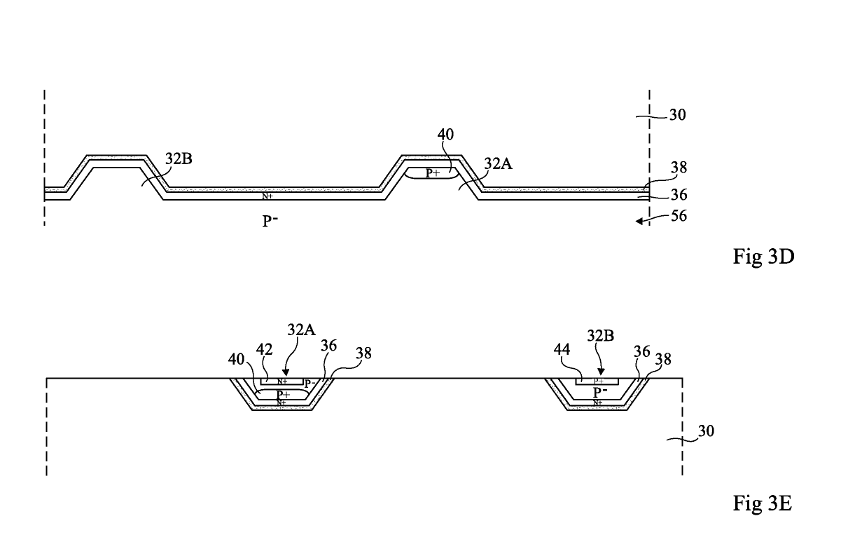

As an example, each island penetrates into insulating substrate 30 down to a depth which may range from 10 to 20 μm, for example, down to a depth equal to 15 μm. As shown in FIG. 2, islands 32A and 32B preferably has inclined sides, the top of each island being wider than the bottom of this island. The inclined sides of the islands enable to facilitate certain steps of the manufacturing of the device of FIG. 2 which are described hereafter in relation with FIGS. 3A to 3E. In top view, not shown, the contour of each island may have the shape of a rectangle, of a square, or of a circle. In this last case, the diameter of the circle is for example in the range from 20 to 50 μm, and may be equal to 30 μm. The distance separating two successive islands is preferably greater than 200 μm.

Due to the fact that the islands are distant from one another, insulating substrate 30 comprises large portions free of islands and passive radio frequency components 46 are formed above these portions of substrate 30. As a result, the radio frequency waves radiating in substrate 30 induce no eddy currents in the substrate. Since substrate 30 is insulating, there is no parasitic coupling between this substrate and metal lines 48 separated from the latter by an insulating layer 50.

FIGS. 3A to 3E are simplified cross-section views schematically illustrating successive steps of an example of an embodiment of a method of manufacturing the device of FIG. 2.

In FIG. 3A, a heavily-doped P-type region 40 (P⁺) is formed in a substrate 56 made of a lightly-doped P-type semiconductor material (P⁻). Region 40 (P⁺) extends from the upper surface of substrate 56. In top view, not shown, region 40 preferably has a shape and dimensions substantially equal to those of the bottom of an island of the type of those shown in FIG. 2. According to the active component(s) which are desired to be formed, region 40 is optional and/or other doped regions may be formed.

In FIG. 3B, the upper surface of semiconductor substrate 56 is etched to form protrusions, two protrusions 32A and 32B being shown in the drawing. After etching, region 40 (P⁺) is located at the top of protrusion 32A. Preferably, the conditions of etching of the upper surface of substrate 56 are selected so that protrusions 32A and 32B have inclined sides.

In FIG. 3C, a heavily-doped N-type layer 36 (N⁺) is formed on the upper surface of semiconductor substrate 56. As an example, layer 36 is formed by implantation of dopant atoms, such an implantation being facilitated by the inclined sides of protrusions 32A and 32B. Layer 36 may also be formed by diffusion from a glass comprising dopant atoms. An optional insulating layer 38 such as a silicon oxide layer may be formed on the upper surface of semiconductor substrate 56, on layer 36 (N⁺). Silicon oxide layer 38 is for example formed by chemical vapor deposition at a temperature lower than 600° C., for example, at 450° C., to avoid affecting the dopant atom concentrations at the level of the N⁺/P⁺ junction between layer 36 and region 40.

In FIG. 3D, an insulating substrate 30 is arranged over the entire upper surface of semiconductor substrate 56 so that insulating substrate 30 follows the shape of the upper surface of semiconductor substrate 56.

According to a first embodiment, insulating substrate 30, for example, an undoped silicon substrate, is previously etched so that the shape of its upper surface is complementary to that of the upper surface of semiconductor substrate 56. In this case, on assembly of substrates 30 and 56, the alignment between these substrates is facilitated by the inclined sides of protrusions 32A and 32B. On assembly, glue may be used to ensure the mechanical stability of the assembly.

According to another embodiment, molten glass having a low melting point (at a temperature smaller than 600° C.) is cast on the upper surface of semiconductor substrate 56 to form insulating substrate 30 therein. In this case, the step of forming insulating layer 38 described in relation with FIG. 3C may be omitted.

In FIG. 3E, the assembly of substrates 30 and 56 is flipped and semiconductor substrate 56 is removed by planarizing etching all the way to the upper surface of insulating substrate 30. Protrusions 32A and 32B of semiconductor substrate 56 then become islands 32A and 32B extending in insulating substrate 30 from its upper surface. In this example additional doping steps are carried out to form a heavily-doped N-type region 42 (N⁺) in island 32A, and a heavily-doped P-type region 44 (P⁺) in island 32B. Islands 32A and 32B identical to those described in relation with FIG. 2 are thus obtained.

Steps, not illustrated, of depositing and etching insulating layers and metal layers on the upper surface of insulating substrate 30 enable to form passive radio frequency components 46 and electric connections between the passive components and terminals of the active components formed in the islands.

To manufacture a device comprising integrated electronic components, the forming of layers, areas, or regions of different doping levels is usually provided. In a device of the type of that of FIG. 2, such areas, layers or regions may be used to form various active components in the islands and to adjust the operating voltages of these active components. The dopant atom concentrations will for example be:

from 10¹⁶ to 10¹⁸ at./cm³ for lightly-doped P-type regions (P⁻),

greater than 5*10¹⁸ at./cm³ for heavily-doped P-type regions (P⁺), and

greater than 10¹⁹ at./cm³ for heavily-doped N-type regions (N⁺).

Specific embodiments have been described. Various alterations, modifications, and improvements will occur to those skilled in the art. In particular, the device described in relation with FIG. 2 is provided in the case where the radio frequency signal applied between pads IN and GND has a negative nominal voltage. It may be provided to invert all the conductivity types of material 34, of layer 36, and of each of regions 40, 42, and 44 in the case where the radio frequency signal has a positive nominal voltage.

It may be provided to form in the islands overvoltage protection components other than those shown in FIG. 1, for example, one-way or bidirectional Shockley diodes. More generally, it may be provided to form in the islands active components having other functions than the protection of radio frequency circuits against overvoltages.

A device comprising a greater number of islands than that shown in FIG. 2 may be provided and, due to the fact that the islands are electrically insulated from one another, the active components of each island may be biased to different voltages.

Although an example of a device comprising a radio frequency circuit associated with an overvoltage protection circuit has been described, it should be understood that such a device may comprise a plurality of radio frequency circuits and/or a plurality of protection circuits comprising active components formed in different islands. For example, a device comprising a plurality of radio frequency circuits, each of which is associated with a different protection circuit, may be provided.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. A device, comprising:
an insulating substrate;
passive radio frequency components formed of portions of metal layers separated by insulating layers that are crossed by vias and laid on an upper surface of the insulating substrate;
wherein islands of a semiconductor material extend into the insulating substrate from said upper surface; and
active integrated circuit components formed in said islands; and
wherein the passive radio frequency components are formed over portions of the insulating substrate that are devoid of islands.

2. The device of claim 1, wherein a circuit of protection against overvoltage is formed from at least some of the active integrated circuit components.

3. The device of claim 1, wherein the active integrated circuit components are connected to the passive radio frequency components.

4. The device of claim 1, wherein a resistivity of the insulating substrate is greater than 10³ Ω·cm.

5. The device of claim 1, further comprising a silicon oxide layer separating the substrate from the semiconductor material of the islands.

6. The device of claim 1, wherein the substrate is made of glass.

7. The device of claim 1, wherein the semiconductor material of the islands is lightly doped with a first conductivity type and comprises a heavily-doped layer of a second conductivity type arranged on edges and a bottom of each island, the semiconductor material of at least one of the islands further comprising a heavily-doped region of the second conductivity type extending from a top of the island, and a heavily-doped region of the first conductivity type in contact, at a bottom of the island, with the heavily-doped layer of the second conductivity type.

8. A method of manufacturing a device, comprising:
a) etching a doped semiconductor substrate of a first conductivity type to form a first surface including protrusions;
b) forming a doped layer of a second conductivity type on the first surface of the semiconductor substrate;
c) arranging an insulating substrate covering and following a shape of the first surface of the semiconductor substrate;
d) removing a portion of the semiconductor substrate to leave the protrusions in the insulating substrate forming semiconductor islands at a planarized surface; and
e) forming passive radio frequency components by depositing and etching insulating layers and metal layers on the planarized surface.

9. The manufacturing method of claim 8, wherein, between step d) and step e), a doped region is formed in at least one of said semiconductor island.

10. The manufacturing method of claim 8, wherein, before step a), another doped region is formed in the semiconductor substrate at a location corresponding to a protrusion.

11. The manufacturing method of claim 8, wherein the etching conditions of step a) are selected so that the protrusions have inclined sides.

12. The manufacturing method of claim 8, wherein step c) comprises depositing molten glass at a temperature lower than 600° C. on the first surface of the semiconductor substrate.

13. The manufacturing method of claim 8, further comprising forming integrated circuits in said semiconductor islands and wherein forming the passive radio frequency components comprises forming the passive radio frequency components over portions of the insulating substrate that are devoid of semiconductor islands.

14. A device, comprising:
an insulating substrate having a top surface;
a semiconductor material island formed in said top surface;
a plurality of insulating layers on the top surface;
metal structures within the insulating layers defining passive electronic radio frequency circuitry;
integrated circuits supported by said semiconductor material island, the integrated circuits comprising plural regions of different conductivity type dopant arranged to form diodes;
wherein the passive electronic radio frequency circuit is electrically connected to the integrated circuits.

15. The device of claim 14, wherein the plural regions of different conductivity type dopant comprise:
a first region having a first conductivity dopant; and
a second region having a second conductivity dopant comprising a layer separating the first region from the insulating substrate.

16. The device of claim 14, wherein the plural regions of different conductivity type dopant comprise:
a first region having a first conductivity dopant; and
a second region having a second conductivity dopant at said top surface and laterally surrounded by said first region.

17. The device of claim 16, wherein the plural regions of different conductivity type dopant further comprise:
a third region having the second conductivity dopant comprising a layer separating the first region from the insulating substrate.

18. The device of claim 17, wherein the plural regions of different conductivity type dopant further comprise:
a fourth region of the having the first conductivity dopant positioned between a portion of the third region and a portion of the first region.

19. The device of claim 14, wherein the plural regions of different conductivity type dopant comprise:
a first region having a first conductivity dopant; and
a second region having the first conductivity dopant at said top surface and laterally surrounded by said first region.

20. The device of claim 19, wherein the plural regions of different conductivity type dopant further comprise:
a third region having a second conductivity dopant comprising a layer separating the first region from the insulating substrate.
